(19) United States
(12) Patent Application Publication
(10) Pub. No.: US 2015/0003014 A1
(43) Pub. Date: Jan. 1, 2015

(54) ELECTRIC APPARATUS

(71) Applicant: ABB Research Ltd, Zurich (CH)

(72) Inventors: Francesco AGOSTINI, Zofingen (CH); Daniele Torresin, Winterthur (CH); Mathieu Habert, Rheinfelden (CH); Bruno Agostini, Zurich (CH)

(73) Assignee: ABB Research Ltd, Zurich (CH)

(21) Appl. No.: 14/315,655

(22) Filed: Jun. 26, 2014

(30) Foreign Application Priority Data
Jun. 27, 2013 (EP) 13173928.6

(51) Int. Cl. H05K 7/20

(52) U.S. Cl. CPC H05K 7/20136; H05K 7/20145; H05K 7/20154
USPC 361/692; 361/695

(57) ABSTRACT

An electric apparatus is disclosed having at least two cooling elements and a first fan arrangement for cooling the at least two cooling elements with a first air flow. A second fan arrangement can cool the at least two cooling elements with a second air flow. The second fan arrangement passes a second air flow in a different flow direction as compared to the first air flow, and the first and second air flows are arranged to cool different parts of the at least two cooling elements.

### RELATED APPLICATION

This application claims priority under 35 U.S.C. §119 to European Patent Application No. 13173928.6 filed in Europe on Jun. 27, 2013, the entire content of which is hereby incorporated by reference in its entirety.

### FIELD

This disclosure relates to an electric apparatus, and a solution for cooling an electric apparatus.

### BACKGROUND INFORMATION

Known fan arrangements are used for providing an air flow via at least two cooling elements, to which electric components are attached, such that the cooling elements receive a heat load produced by the electric components. The air flow passing via the cooling elements receives the heat load from the cooling elements and forwards it to the surroundings.

However, different cooling elements can receive a different amount of cooling. The originally relatively cold air passes a first cooling element where the air is heated as it cools the first cooling element. Therefore, subsequent cooling elements in the flow direction of the air will receive air that has been heated by the previous cooling elements. In an implementation involving many cooling elements in series, the temperature of the air flow will rise for each subsequent cooling element that the air flow reaches. This is referred to as thermal stacking.

One common attempt to handle the above described problem of cooling elements operating at different temperatures is to increase the volumetric flow of air. However, this involves a larger fan and can increase the pressure drop, energy consumption and noise.

### SUMMARY

An electric apparatus is disclosed comprising: at least two cooling elements for cooling electric components by receiving a heat load produced by the electric components; a first fan arrangement for cooling at least two cooling elements with a first air flow, and a second fan arrangement for cooling the at least two cooling elements with a second air flow, the second fan arrangement being arranged to supply a second air flow in a different flow direction as compared to the first air flow; and wherein the first and second air flows are arranged to cool different parts of the at least two cooling elements.

### BRIEF DESCRIPTION OF DRAWINGS

In the following discussion, features disclosed herein will be described in more detail by way of example and with reference to the attached drawings, in which:

FIG. 1 illustrates an exemplary embodiment of an apparatus disclosed herein;

FIGS. 2 and 3 illustrate an exemplary embodiment of a cooling element disclosed herein;

FIGS. 4 and 5 illustrate a temperature behaviour in the first exemplary embodiment of FIG. 1;

FIG. 6 illustrates a second exemplary embodiment of an apparatus disclosed herein;

FIG. 7 illustrates a third exemplary embodiment of an apparatus disclosed herein; and

FIG. 8 illustrates a fourth exemplary embodiment of an apparatus disclosed herein.

### DETAILED DESCRIPTION

An electric apparatus with an improved cooling solution is disclosed herein.

The use of two different air flows with different flow directions makes it possible to ensure that each cooling element and the corresponding electric components receive even and adequate cooling.

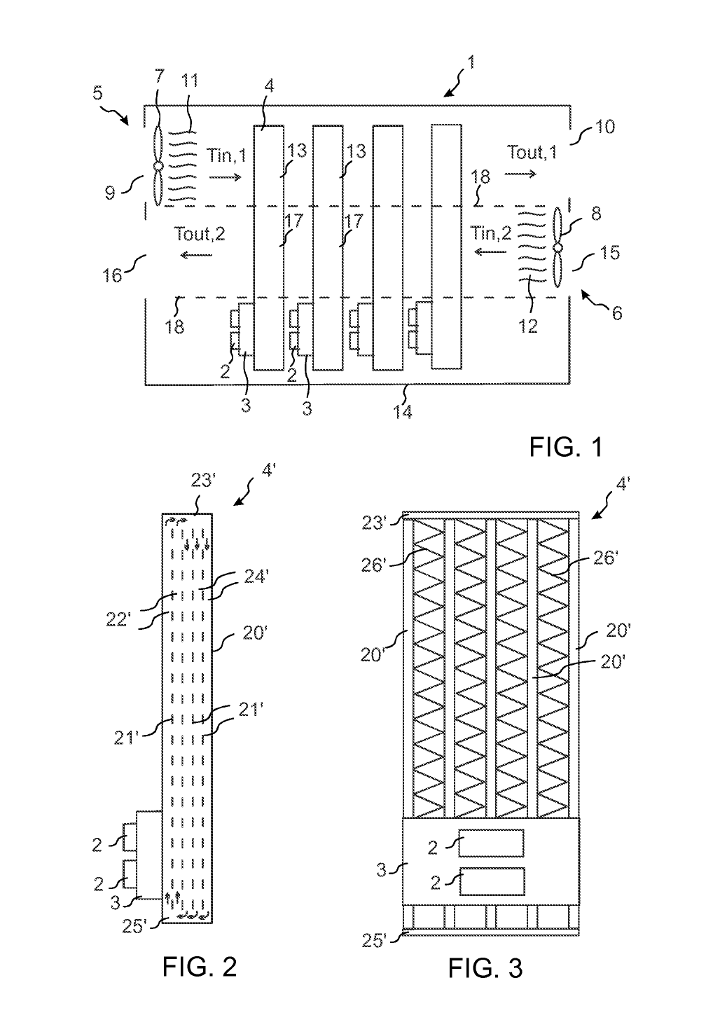

FIG. 1 illustrates a first exemplary embodiment of an apparatus as disclosed herein. The illustrated electric apparatus 1 may be a motor drive providing an electrical motor with electric power, such as a frequency converter for instance.

In the illustrated example the electric components 2 are attached via base plates 3 to cooling elements 4. Base plates are, however, not necessary in all implementations. Heat produced by the electric components during their use is conducted to the cooling elements 4. In the illustrated example, the first ends of the substantially parallel cooling elements 4 are provided with electric components 2, while the opposite, second ends of the cooling elements are arranged in an air flow.

The cooling elements 4 may be manufactured of aluminum or of another suitable material such as any material with excellent heat conducting properties, for instance. In their simplest form the cooling elements 4 may include (e.g., consist of) heat sinks whose metal material, for instance, conducts heat from the electric components 2 to the air flow. However, as an alternative, it is possible to utilize more sophisticated and efficient cooling elements. Such cooling elements may include an internal fluid circulation, for instance. It is also possible to utilize pulsating heat pipes or two-phase thermosyphons, as illustrated in FIGS. 2 and 3.

In the example according to FIG. 1, the apparatus includes a first fan arrangement 5 and a second fan arrangement 6 including separately a first fan 7 and a second fan 8. The first fan 7 generates a first air flow from a first inlet 9 to a first outlet 10. This first airflow 11 cools a first part 13 of the cooling elements 4, which in the illustrated example is the uppermost ends of the cooling elements. The first airflow 11 entering the housing or component space 14 via the first inlet 9 has a temperature Tin,1 and the airflow 11 exiting the housing via the first outlet 10 has a temperature Tout,1.

The second fan 8 generates a second air flow 12 from a second inlet 15 to a second outlet 16. The second airflow 12 cools a second part 17 of the cooling elements 4, which in the illustrated example is located in the middle of the cooling elements 4. The second airflow 12 entering the housing or component space 14 via the second inlet 15 is Tin,2 and the airflow 12 exiting the housing or component space 14 via the second outlet 16 is Tout,2.

One or more intermediate walls 18 may extend between the cooling elements 4 to direct the first and second air flows to different parts of the cooling elements 4. Such intermediate walls are not necessary in all embodiments. If intermediate walls are used, tightness is not important but a reasonable amount of leakage may be allowed. An object of exemplary embodiments is, however, to ensure that the first 11 and second 12 air flows, which have different flow directions, do not mix up to an significant extent, but instead the flows occur generally as has been illustrated and explained to cool different parts of the cooling elements. In FIG. 1 two intermediate walls 18 have been illustrated by way of example. The intermediate wall 18, which is located lower in FIG. 1, prevents the second air flow from reaching the lower ends of the cooling elements 4, where the electric components 2 are located, and the upper intermediate wall 18 keeps the first airflow 11 and second airflow 12 apart from each other.

Though the electric apparatus in FIG. 1 is arranged in a housing 14, such a housing is not necessary in all embodiments.

In FIG. 1 the cooling elements 4 are arranged in a series configuration with a distance (air gap) between the cooling elements 4 and the respective electric components 2 attached to them. However, as an alternative, the cooling elements in FIG. 1 could be arranged in a stacked configuration, where the cooling elements 4 and/or the electric components 2 contact (thermal contact) each other.

As explained herein, the flow direction of the second air flow is different than the flow direction of the first air flow. In exemplary implementations, a most efficient solution is to have opposite flow directions. However, exactly opposite flow directions are not necessary in all embodiments, as a sufficiently efficient cooling is also accomplished when the flow directions are different, in other words, not exactly opposite to each other.

FIGS. 2 and 3 illustrate an exemplary embodiment of a cooling element. The cooling element 4′ of FIGS. 2 and 3 is very similar to the cooling elements 4 explained in connection with FIG. 1. Therefore, the cooling element of FIGS. 2 and 3 will mainly be explained by pointing out the differences.

The cooling element 4′ of FIGS. 2 and 3 may be utilized in the electric apparatus of FIG. 1. The cooling element 4′ is a two-phased thermosyphon with an internal fluid circulation. The cooling element 4′ can include a plurality of pipes 20′ arranged side by side, such as in parallel. Each pipe is divided by internal walls 21′ into a plurality of flow channels.

In the illustrated example, the two flow channels located most to the left in FIG. 2 are evaporator channels 22′ receiving a heat load from the electric components 2 via the base plate 3. Consequently, the fluid evaporates and moves upwards. A manifold 23′ in the second upper end of the cooling element returns the fluid via condenser channels 24′ to a manifold 25′ in a first lower end of the cooling element 4′.

Between the condenser channels 24′, fins 26′ are arranged in order to transfer heat from the condenser channels 24′ to the passing airflow. Therefore, the fluid condensates and returns for a new cycle in the evaporator channels 25′. In order to increase the fluid circulation, some of the channels may have capillary dimensions.

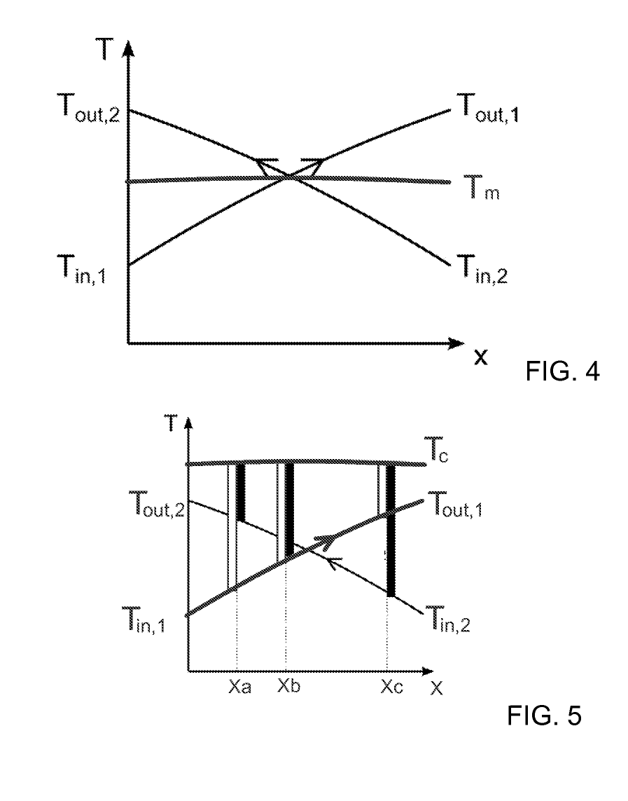

FIGS. 4 and 5 illustrate the temperature behaviour in the first embodiment of the apparatus as illustrated in FIG. 1. In this example, it is by way of example assumed that the flow directions of the first and second air flows are opposite (counter-current flows), as illustrated in FIG. 1.

In FIG. 4 the temperature T is plotted as a function of the coordinate X across the cooling elements 4 in FIG. 1. As can be seen in FIG. 4, the temperature Tin,1 of the first air flow 11 is low when the first air flow enters the first inlet 9. After having passed the cooling elements 4, the temperature Tout,1 of the first air flow 11 is much higher, when it exits via the first outlet 10. The second air flow 12 similarly has a low temperature Tin,2 at the second inlet 15 and a much higher temperature Tout,2 at the second outlet 16. The illustrated temperature profile is obtained as both air flows 11 and 12 have the same flow volume and as it is assumed that the power losses for the electric components of all cooling elements are the same.

As can be seen in FIG. 4, due to the opposite flow directions, each cooling element 4, irrespective of its location on the flow path of the first and second air flow, will “feel” an average temperature Tm of the surrounding air. Therefore, thermal stacking can be avoided.

FIG. 5 illustrates an exemplary situation in more detail. The white bars represent the top channel in FIG. 1 and the relative temperature evolution, and the black bars represent the bottom channel in FIG. 1.

Assuming the same volumetric flow rate and same inlet temperature for both streams, the condenser will “feel” an average operation air temperature Tm as represented in FIG. 4, and the condenser will operate at an almost constant saturation temperature (e.g., ±5%) represented in the graph of FIG. 5 as Tc. To better understand the process, we proceed across the coolers series from left to right and we place ourselves at position Xa. The white and black bars are proportional to the heat exchanged in each subsection (top and bottom one respectively). If now we proceed further across the device starting from Xa, we can identify at each position Xn the heat exchanged by each part of the condenser from the color bars. The total heat exchanged at each point (sum of the heat exchanged by each subsections) is almost constant.

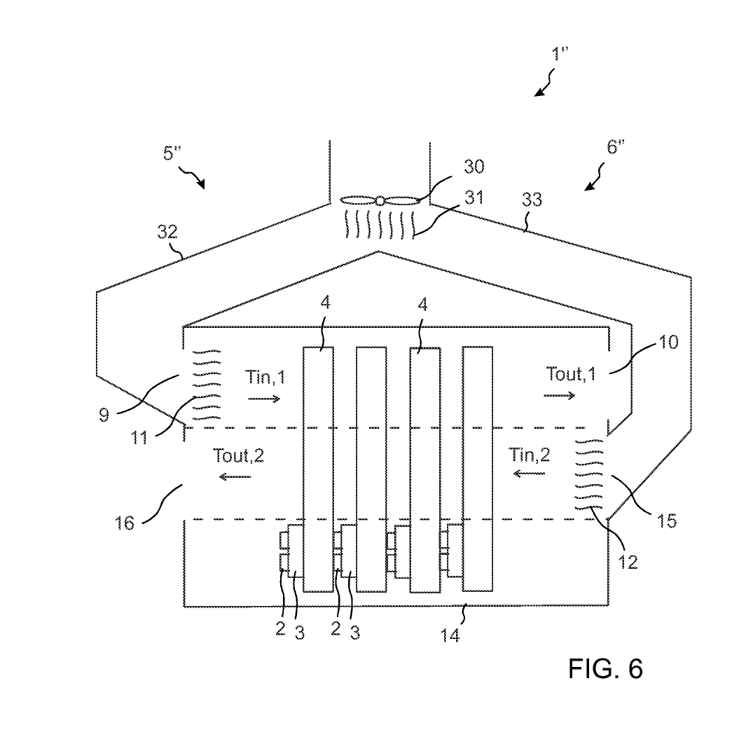

FIG. 6 illustrates a second exemplary embodiment of an apparatus. The embodiment of FIG. 6 is very similar to the one of FIG. 1. Therefore, the embodiment of FIG. 6 will be explained mainly by pointing out the differences between these embodiments.

In FIG. 6 the cooling elements 4 are arranged in a stacked configuration, where the cooling elements 4 with their respective electric components 2 contact (thermal contact) each other. However, this is only by way of example. In practice, it is also possible to utilize the series configuration illustrated in FIG. 1 in the embodiment of FIG. 6.

In FIG. 6 the first 5″ and second 6″ fan arrangements can include one single fan 30 only generating one air flow 31. The first 5″ and second 6″ fan arrangements also can include a flow channel 32 and 33 splitting the air flow into the first and second air flows 11 and 12 with different flow directions that in the illustrated example are opposite.

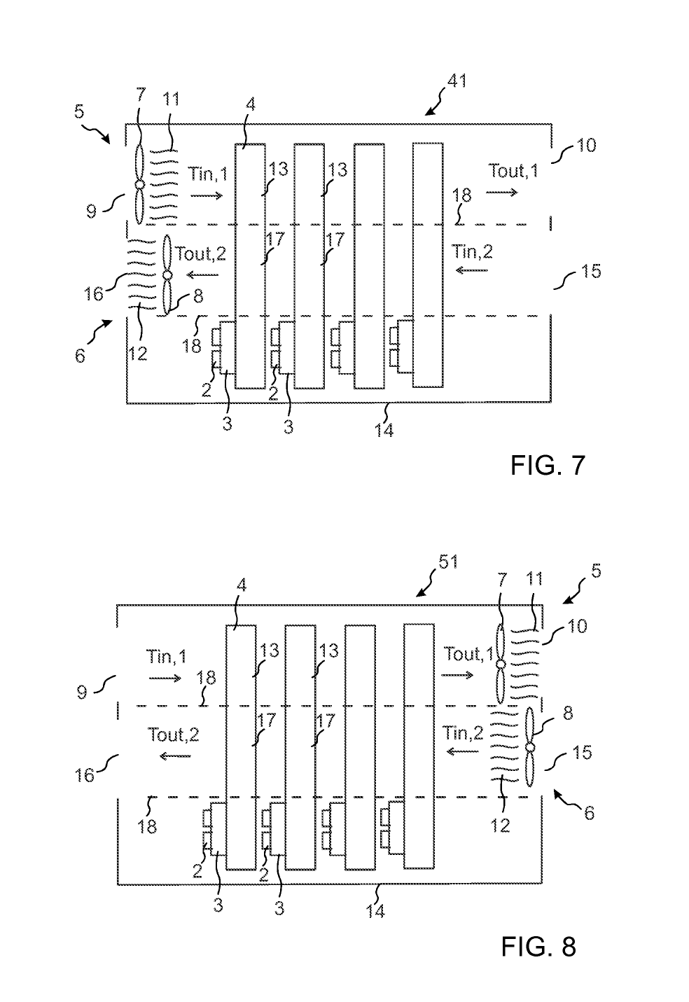

FIG. 7 illustrates a third exemplary embodiment of an apparatus 41. The embodiment of FIG. 7 is similar as the one explained in connection with FIG. 1 except for the location of the second fan 8. In the embodiment of FIG. 7 the second fan is arranged close to the second outlet 16 where it sucks air through the second inlet 15 and pushes it further through the second outlet.

FIG. 8 illustrates a third exemplary embodiment of an apparatus 51. The embodiment of FIG. 8 is similar as the one explained in connection with FIG. 1 except for the location of the first fan 7. In the embodiment of FIG. 8 the first fan is arranged close to the first outlet 10 where it sucks air through the first inlet 9 and pushes it further through the first outlet 10.

In the illustrated examples and in the above explanations, two air flows cooling different parts of the same cooling elements are illustrated. However, more than two air streams cooling different parts of the same cooling elements can naturally be utilized. Also, in this case, flow directions of the different air flows can be advantageously different.

It is to be understood that the above description and the accompanying figures are only intended to illustrate features disclosed herein. It will be apparent to those person skilled in the art that features of the invention can be varied and modified without departing from the scope of the invention.

Thus, it will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

1. An electric apparatus comprising:
at least two cooling elements for cooling electric components by receiving a heat load produced by the electric components;
a first fan arrangement for cooling at least two cooling elements with a first air flow; and
a second fan arrangement for cooling the at least two cooling elements with a second air flow, the second fan arrangement being arranged to supply a second air flow in a different flow direction as compared to the first air flow; and wherein
the first and second air flows are arranged to cool different parts of the at least two cooling elements.

2. An electric apparatus according to claim 1, wherein the first fan arrangement comprises:
a first fan, and the second fan arrangement comprises a second fan.

3. An electric apparatus according to claim 1, wherein the first and second fan arrangements comprise:
one single fan for generating an air flow; and
a flow channel for splitting the air flow into the first and second air flows.

4. An electric apparatus according to claim 1, wherein one or more intermediate walls extend between the at least two cooling elements for directing first and second air flows to different parts of the at least two cooling elements.

5. An electric apparatus according to claim 1, in combination with electric components, wherein the at least two cooling elements with respective electric components attached to them are arranged in a series configuration with a distance between the at least two cooling elements and the respective electric components attached to them.

6. An electric apparatus according to claim 1, in combination with electric components, wherein the at least two cooling elements with the respective electric components attached to them are arranged in a stacked configuration to contact each other.

7. An electric apparatus according to claim 1, in combination with electric components, wherein the at least two cooling elements with the respective electric components are arranged in a component space which is surrounded by walls, the walls comprising:
first and second inlets, and first and second outlets for passing the first and second air flows through the component space.

8. An electric apparatus according to claim 1, wherein the at least two cooling elements are two-phase thermosyphons or pulsating heat pipes.

9. An electric apparatus according to claim 1, wherein the second fan arrangement is arranged for supplying the second air flow in an opposite flow direction as compared to the first air flow.

10. An electric apparatus according to claim 2, wherein one or more intermediate walls extend between the at least two cooling elements for directing first and second air flows to different parts of the at least two cooling elements.

11. An electric apparatus according to claim 3, wherein one or more intermediate walls extend between the at least two cooling elements for directing first and second air flows to different parts of the at least two cooling elements.

12. An electric apparatus according to claim 10, in combination with electric components, wherein the at least two cooling elements with respective electric components attached to them are arranged in a series configuration with a distance between the at least two cooling elements and the respective electric components attached to them.

13. An electric apparatus according to claim 11, in combination with electric components, wherein the at least two cooling elements with respective electric components attached to them are arranged in a series configuration with a distance between the at least two cooling elements and the respective electric components attached to them.

14. An electric apparatus according to claim 12 in combination with electric components, wherein the at least two cooling elements with the respective electric components attached to them are arranged in a stacked configuration to contact each other.

15. An electric apparatus according to claim 13, in combination with electric components, wherein the at least two cooling elements with the respective electric components attached to them are arranged in a stacked configuration to contact each other.

16. An electric apparatus according to claim 14, in combination with electric components, wherein the at least two cooling elements with the respective electric components are arranged in a component space which is surrounded by walls, the walls comprising:
first and second inlets, and first and second outlets for passing the first and second air flows through the component space.

17. An electric apparatus according to claim 15, in combination with electric components, wherein the at least two cooling elements with the respective electric components are arranged in a component space which is surrounded by walls, the walls comprising:
first and second inlets, and first and second outlets for passing the first and second air flows through the component space.

18. An electric apparatus according to claim 16, wherein the at least two cooling elements are two-phase thermosyphons or pulsating heat pipes.

19. An electric apparatus according to claim 17, wherein the at least two cooling elements are two-phase thermosyphons or pulsating heat pipes.

20. An electric apparatus according to claim 18, wherein the second fan arrangement is arranged for supplying the second air flow in an opposite flow direction as compared to the first air flow.
